(19) United States
(12) Patent Application Publication
(10) Pub. No.: US 2007/0298615 A1
(43) Pub. Date: Dec. 27, 2007

(54) PATTERN FORMING METHOD AND METHOD OF MANUFACTURING SEMICONDUCTOR DEVICES

(76) Inventors: Nobuyuki Matsuzawa, Tokyo (JP); Atsuhiro Ando, Nagasaki (JP); Eriko Matsui, Tokyo (JP); Yuko Yamaguchi, Kanagawa (JP); Katsuhisa Kugimiya, Kanagawa (JP); Tetsuya Tatsumi, Kanagawa (JP); Salam Kazi, Kanagawa (JP); Takeshi Iwai, Kawasaki (JP); Makiko Irie, Kawasaki (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/668,679

(22) Filed: Jan. 30, 2007

(30) Foreign Application Priority Data
Feb. 17, 2006 (JP) P2006-041209

(51) Int. Cl. H01L 21/311

(52) U.S. Cl. 438/694; 257/E21.023

(57) ABSTRACT

A pattern forming method is provided. The pattern forming method includes a first step of forming a resist pattern including a lactone group-containing skeleton above an etched layer provided on a substrate; a second step of performing plasma processing using a hydrogen-containing gas to lower a glass transition temperature or a softening point of the resist pattern; and a third step of transferring the resist pattern after the plasma processing to the etched layer by etching, and forming the pattern of the etched layer.

### CROSS REFERENCES TO RELATED APPLICATIONS

The present invention contains subject manner related to Japanese Patent Application JP 2006-041209 filed in the Japanese Patent Office on Feb. 17, 2006, the entire contents of which being incorporated herein by reference.

### BACKGROUND OF THE INVENTION

1. Field of the Invention

The present invention relates to a pattern forming method and a method of manufacturing semiconductor devices, more specifically, to a pattern forming method and a method of manufacturing semiconductor devices that use a resist pattern including a lactone group-containing skeleton for a mask.

2. Description of the Related Art

A lithography method and a method of plasma etching on an etched layer using a resist pattern formed by the lithography method as a mask are frequently used for manufacturing a fine structure in various kinds of electronic devices such as semiconductor devices and liquid crystal devices. In accordance with miniaturization of a device structure, miniaturization of a pattern of the etched layer after the plasma etching has been desired.

Presently, for example, a fine pattern of an etched layer can be formed with a line width of about 65 nm by a lithography method and by a plasma etching method after the lithography method in the cutting-edge technology. However, a finer pattern is further desired to be formed. In such fine pattern with nanometer-order high resolution, a ratio of edge-roughness to line width of the pattern is high, and it is more difficult to reduce the edge roughness of the pattern than the past. Therefore the improvement in reducing the edge roughness is more desired.

For example, dispersion of gate line widths of transistors may be required to be 2.2 nm or less in the generation of 65 nm semiconductors and to be 1.6 nm or less in the generation of 45 nm semiconductors (for example, refer to “International Technology Roadmap for Semiconductors”, ITRS, [online] year 2003 edition, Tables 77a and 77b, (searched on Feb. 6, 2006), Internet <URL: http;//public.itrs.net>). Specifically, dispersion of line widths in an etched layer on which patterning is performed by etching using a resist pattern as a mask may be required to be equal to or less than the above-described values.

Accordingly, various methods have been studied in order to reduce the dispersion of the line widths of the pattern of the etched layer. For example, there is proposed a method of reducing edge roughness of a resist pattern by curing a resist film by plasma processing using a HBr (Hydrogen Bromide) gas. In this method, the edge roughness in the pattern of the etched layer was reduced after performing the patterning of the etched layer using the resist pattern (for example, refer to A. P. Maholowara, et al; Proceedings of SPIE, Vol. 57531 pp. 380; 2005, USA).

Further, as another example, Japanese Unexamined Patent Application Publication No. 2003-68602 discloses a method of reducing the edge roughness in the resist pattern by gradually changing the baking temperature in PEB (Post Exposure Baking) of the resist film. With this method also, the edge roughness of the etched layer was reduced.

### SUMMARY OF THE INVENTION

However, the edge roughness in the resist pattern is not sufficiently reduced by using the above-described method in which the resist film is cured by the plasma processing using a HBr gas and by using the above-described method in which the baking temperature in the PEB is gradually changed. Accordingly, if the patterning is performed on an etched layer by the etching using the resist pattern as a mask, the edge roughness in the pattern of the etched layer is not reduced sufficiently.

In view of the above, it is desirable to provide a pattern forming method and a method of manufacturing semiconductor devices, in which dispersion of line widths of a pattern of an etched layer can be reduced.

A pattern forming method according to an embodiment of the present invention includes the following steps performed successively. In a first step, a resist pattern including a lactone group-containing skeleton is formed above an etched layer provided on a substrate. In a second step, plasma processing using a hydrogen-containing gas is performed to lower a glass transition temperature or a softening point of the resist pattern. In a third step, the resist pattern after the plasma processing is transferred to the etched layer by etching to form the pattern of the etched layer. It should be noted that a “lactone group” according to an embodiment of the present invention is obtained by removing one hydrogen atom from lactone.

According to such pattern forming method, the lactone group included in the resist pattern is eliminated from a polymeric material constituting the resist pattern by performing the plasma processing using the hydrogen-containing gas in the second step. Then, the eliminated lactone group remains in the resist pattern, and functions as a plasticizer, thereby lowering a glass transition point or a softening point of the resist pattern and softening the resist pattern. Accordingly, a surface of the resist pattern is planarized in comparison with the case of not performing the above-described plasma processing, and consequently the edge roughness is reduced. Therefore, the edge roughness of the pattern of the etched layer is reduced by transferring the resist pattern to the etched layer by the etching in the third step.

Further, a method of manufacturing semiconductor devices according to an embodiment of the present invention, in which the above-described pattern forming method is applied to forming gate electrodes, is provided including the following steps performed successively. In a first step, a resist pattern including a lactone group-containing skeleton is formed above a gate electrode film provided on a substrate. In a second step, plasma processing using a hydrogen-containing gas is performed to lower a glass transition temperature or a softening point of the resist pattern. In a third step, the resist pattern after the plasma processing is transferred to the gate electrode film by etching to form the gate electrodes.

According to such method of manufacturing semiconductor devices, the edge roughness of gate electrodes, specifically, the gate LWR (Line Width Roughness) is reduced by applying the above-described pattern forming method to forming the gate electrodes.

As described above, with the pattern forming method according to an embodiment of the present invention, the pattern can be formed accurately, because dispersion of the line width of the pattern is controlled by reducing the edge roughness of the pattern of the etched layer. Further, according to the method of manufacturing semiconductor devices in which the pattern forming method is used, dispersion of element characteristics is controlled, because the dispersion of the gate line widths is reduced by reducing the LWR, and consequently the performance of the semiconductor devices can be improved.

### BRIEF DESCRIPTION OF THE DRAWINGS

FIGS. 1A to 1D are sectional views showing steps (first part) for explaining a pattern forming method and a method of manufacturing semiconductor devices according to an embodiment of the present invention;

FIGS. 2A and 2B are sectional views showing steps (second part) for explaining a pattern forming method and a method of manufacturing semiconductor devices according to an embodiment of the present invention;

FIG. 3 is a graph showing distribution of LWR (3σ) in a resist pattern with or without plasma processing using a HBr gas; and

FIG. 4 is a graph showing distribution of LWR (3σ) in the case where plasma processing using a HBr gas is performed on a resist pattern in which weight percent (wt %) of lactone group-containing skeleton is different.

### DESCRIPTION OF THE PREFERRED EMBODIMENTS

Embodiments according to the present invention are hereinafter explained in detail with reference to the drawings.

<Resist Material>

First, explanation is given to resist materials used for a pattern forming method and a method of manufacturing semiconductor devices according to an embodiment of the present invention. The resist materials include a polymeric material having a lactone group-containing skeleton. Here, the following structural formula (1) is an example of a structural formula of the polymeric material. It should be noted that 1, m and n in the structural formula (1) are positive integers, respectively.

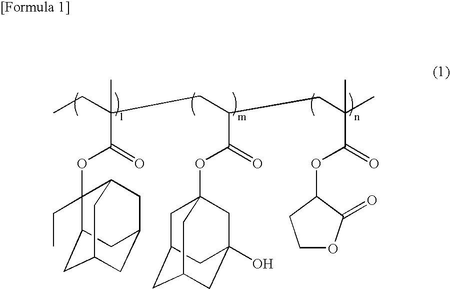

As is shown in the above structural formula (1), the polymeric material is an acrylic resin including a lactone group-containing skeleton. Specifically, copolymers of methacrylic ester and acrylic ester constituting a backbone chain with an ester-bond side chain form a skeleton unit including three kinds of ester. Two of those kinds are an adamantyl group-containing skeleton including methacrylic acid and 2-ethyl-adamantyl group ester, and an adamantyl group-containing skeleton including acrylic acid and 3-hydroxy-adamantyl group ester, and the remaining unit is a lactone group-containing skeleton including methacrylic acid and γ-butyrolactone group ester.

Here, a resist material used for the pattern forming method according to an embodiment of the present invention preferably includes the lactone group-containing skeleton of 20 wt % or more and 35 wt % or less based on the polymeric material. When the lactone group-containing skeleton is 20 wt % or more, the glass transition temperature or softening point of the resist pattern remarkably falls by plasma processing using a hydrogen-containing gas and edge roughness of the resist pattern is remarkably reduced as described later on. Further, when the lactone group-containing skeleton is 35 wt % or less, a sufficient etching tolerance is presented.

It should be noted that an example in which a lactone group in the lactone group-containing skeleton is a γ-butyrolactone group is explained, however, the lactone group may be a norbornene lactone (2, 6-norbornene carbolactone) group or another lactone group. Further, the lactone group-containing skeleton here includes methacrylic acid and lactone group (γ-butyrolactone group) ester, but the methacrylic acid may be other carbolic acid such as acrylic acid or may be other compounds capable of bonding to lactone groups as long as a lactone group is contained.

Further, the other structure than the lactone group-containing skeleton is not limited to an example of the above-described structural formula (1). It may be sufficient if the lactone group-containing skeleton is included in the polymeric material. For example, regarding the adamantyl group-containing skeleton, an example of methacrylic acid and 2-ethyl-adamantyl group ester and an example of acrylic acid and 3-hydroxy-adamantyl group ester are explained. However, the methacrylic acid may be an acrylic acid and the acrylic acid may be a methacrylic acid. Further, the 2-ethyl-adamantyl group may be another adamantyl group such as a 2-methyl-adamantyl group, and there is no particular limitation regarding a 3-hydroxy-adamantyl group. Furthermore, the skeleton unit may include other skeletons than the adamantyl group-containing skeleton.

The example in which the backbone chain includes the copolymer formed of the methacrylic ester and acrylic ester is heretofore explained. However, the backbone chain may include homopolymer formed of methacrylic ester or acrylic ester and may include two or more kinds of skeleton unit. Further, although a block copolymer arranged by respective skeleton units is described in the structural formula (1), there is no specific limitation on the order of arrangement of the skeleton units. Hence, a random copolymer in which respective skeleton units are randomly arranged may be used instead of such block copolymer. The random copolymer is preferable.

Then, the polymeric material as described above, and other additives such as a photoacid generators a quencher element, for example, amine that controls diffusion of a generated acid, a surfactant are dissolved into a solvent to obtain a chemical amplification resist material having photo sensitivity.

[Pattern Forming Method]

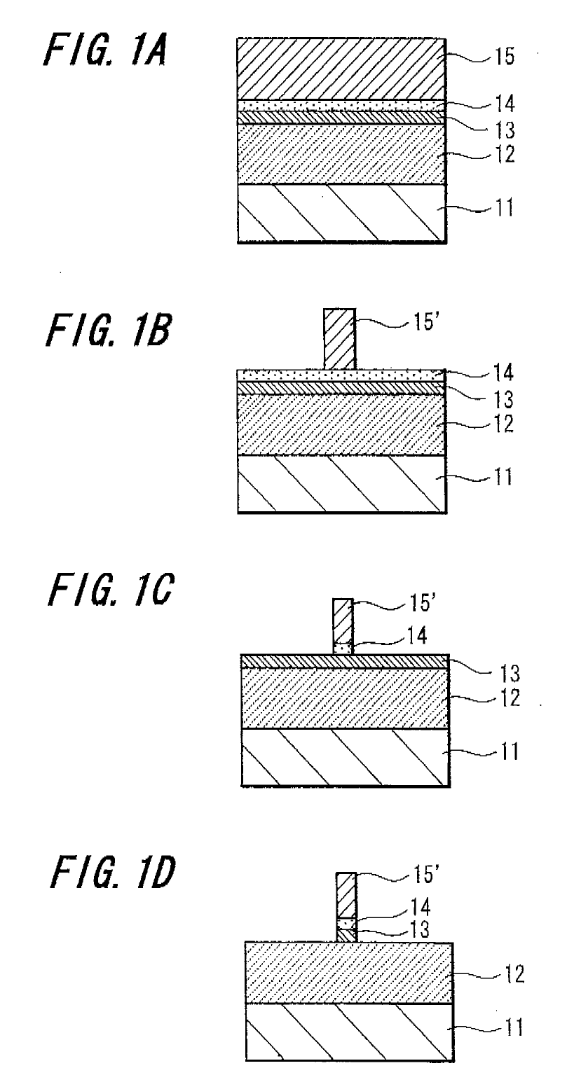

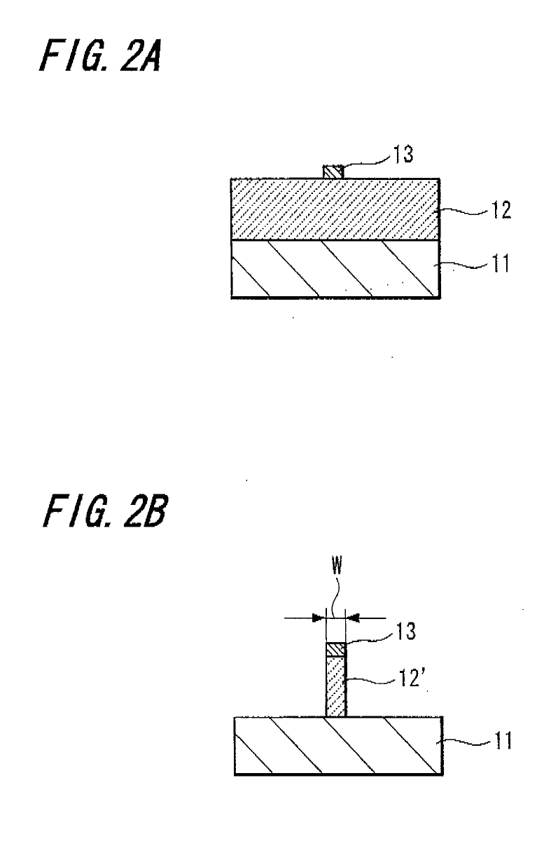

Next, a method of forming gate electrodes according to an embodiment of a method of forming patterns and a method of manufacturing semiconductor devices of the present invention, in which the above-described resist materials are used, is explained using sectional views of FIGS. 1 and 2.

First, as shown in FIG. 1A, a gate electrode film 12 made of, for example, polysilicone is formed on a substrate 11, for example, silicone wafer through a gate-insulated film, for example, oxide silicone film (not shown in the figure). Next, after a protective film 13 made of TEOS (tetraethoxysilane), for example, is formed on the gate electrode film 12, an antireflective coating 14 made of thermosetting resin, for example, is formed on the protective film 13 by a spin-coating method, for example, and baking treatment is performed. Subsequently, the above-described resist material is applied to the antireflective coating 14 by the spin-coating method for example, and after a resist film 15 is formed, baking treatment is performed.

Next, as shown in FIG. 1B, the resist film 15 (see FIG. 1A) is exposed for baking treatment, and is developed to form a resist pattern 15′ using an alkali developer. Roughness is observed on the edge of the resist pattern 15′.

Subsequently, as shown in FIG. 1C, the resist pattern 15′ is transferred to the antireflective coating 14, and patterning is performed on the antireflective coating 14. After that, trim etching is performed on the resist pattern 15′ and on the pattern of the antireflective coating 14, thereby causing line widths of the resist pattern 15′ and the pattern of antireflective coating 14 to be thin.

Plasma processing using a hydrogen-containing gas is performed on the substrate 11 in such state. Here, a HBr (Hydrogen bromide) gas is used, for example. In this example of plasma processing, conditions are set as follows: a flow rate of the HBr gas is 40 ml/min, source power is 300 W, pressure is 0.53 Pa, and processing time is 10 sec. Further, a temperature of a stage holding the substrate 11 is set to 50° C.

With the above plasma processing being performed, the lactone group within the resist pattern 15′ is eliminated from the polymeric material. Then, the eliminated free lactone group remains in the resist pattern 15′ and serves as a plasticizer to lower the glass transition point or softening point of the resist pattern 15′, causing the resist pattern 15′ to be softened. Accordingly, a surface of the resist pattern 15′ is planarized, and consequently the edge roughness is reduced. Particularly, etching tolerance can be maintained and the edge roughness of the resist pattern 15′ can be reduced remarkably, with the lactone group-containing skeleton being 20 wt % or more and 35 wt % or less based on the polymeric material constituting the resist pattern 15′.

In a verification test described later on, it was confirmed that the residual of the free lactone group in the resist pattern 15′ increased particularly when using the hydrogen-containing gas for the above plasma processing, in comparison with the case in which a tetrafluoromethane (CF₄) gas or a chlorine (Cl₂) gas was used. Further, according to the verification test, it was confirmed that the fall of the glass transition temperature or softening point of the resist pattern 15′ depended upon the remaining quantity of the free lactone group in the resist pattern 15′ and that the glass transition temperature or softening point remarkably fell in the case where the resist material including the lactone group-containing skeleton by more wt % was used.

An example using the HBr gas for the plasma processing is explained in the above. However, it should be noted that a gas including hydrogen capable of generating hydrogen plasma may be used. Other than the HBr, hydrogen chloride (HCl), hydrogen iodide (HI), and hydrogen (H₂) can also be used. Further, oxygen (O₂) or inert gas may be supplied together with a hydrogen-containing gas. However, in the case where the O₂ gas or inert gas is used together with the hydrogen-containing gas, processing conditions are adjusted so that the resist pattern 15′ may not be etched by the plasma processing.

When performing thermal treatment between the above plasma processing and the later described etching of the protective film 13 using the resist pattern 15′ as a mask, the resist pattern 15′ is further softened and the edge roughness is further reduced. It is preferable that the thermal treatment is performed at a temperature higher than the lowered glass transition temperature or softening point.

For example, the plasma processing may be performed also to serve as the above thermal treatment, or the thermal treatment may be performed between the plasma processing and the later-described etching of the protective film 13. Further, the etching of the protective film 13 may be performed also to serve as the thermal treatment.

The above thermal treatment may be performed by heating the substrate 11, but temperature rise in the resist pattern 15′ by the plasma processing or etching may be used as the thermal treatment, in the case where the plasma processing or the etching of the protective film 13 is performed also to serve as the thermal treatment.

After the plasma processing, the resist pattern 15′ is sequentially transferred to the lower-layer side by etching. First, as shown in FIG. 1D, patterning of the protective film 13 is performed by etching using the resist pattern 15′ as a mask. In that case, because the edge roughness of the resist pattern 15′ has been reduced, the transfer is performed in the state in which the reduction of the edge roughness is maintained and the edge roughness of the protective film 13 is also reduced.

Next, as shown in FIG. 2A, the above resist pattern 15′ (see FIG. 1D) and the antireflective coating 14 (see FIG. 1D) are removed by ashing and the pattern of the protective film 13 is exposed.

Subsequently, as shown in FIG. 2B, patterning is performed on the gate electrodes 12 (see FIG. 2A) to form gate electrodes 12′ by the etching using the pattern of the protective film 13 as a mask. In that case, as described above, because the edge roughness of the protective film 13′ is reduced, the transfer is performed in the state in which the reduction of the edge roughness is maintained and the edge roughness of the gate electrodes 12′ is also reduced. Accordingly, roughness of the gate line width W (LRW) is reduced.

According to the pattern forming method and the method of manufacturing semiconductor devices using such method, edge roughness of the resist pattern 15′ is reduced by performing plasma processing using the HBr gas. Accordingly, the LWR is reduced when transferring the resist pattern 15′ to the gate electrode film 12 by etching. Therefore, since the dispersion of the gate line widths W is reduced, the dispersion of element characteristics can be controlled and the performance of the semiconductor devices can be improved.

In the above embodiment, the plasma processing is performed after the trim etching of the resist pattern 15′, as explained using FIG. 1C. However, it should be noted that the plasma processing may be performed after forming the resist pattern 15′ which is explained using FIG. 1B and before the patterning of the antireflective coating 14, or the plasma processing may be performed after the patterning of the antireflective coating 14 and before the trim etching. Further, the trim etching may be performed using a hydrogen-containing gas. However, in order to etch the resist pattern 15′ in that case, the plasma processing condition may be adjusted suitably such that oxygen is added to a hydrogen-containing gas, or the like.

Further, in the above embodiment, the gate electrodes 12′ is formed by transferring the resist pattern 15′ to the protective film 13 and by transferring the pattern of the protective film 13 to the gate electrode film 12 by etching. However, an embodiment of the present invention can be applied to the case where without forming the protective film 13 the patterning is directly performed on the gate electrode film 12 by etching using the resist pattern 15′ as a mask. In that case, the thermal treatment after the plasma processing may be performed also to serve as the etching of the gate electrode film 12.

[Verification Test 1]

A verification test was carried out regarding the fall of a glass transition temperature of a resist film by the plasma processing using the hydrogen-containing gas. First, polymeric materials A to D (hereinafter termed materials A to D) each including the lactone group-containing skeleton shown in the following structural formula (2) having different wt % were prepared.

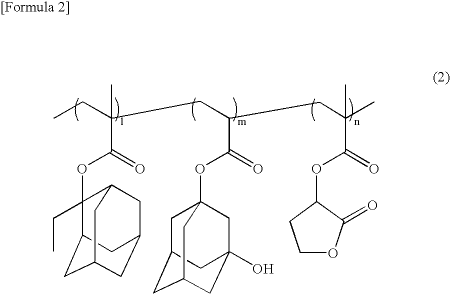

The number of 1, m and n, and wt % of the lactone group-containing skeleton of the materials A to D are shown in Table 1. As shown in Table 1, wt % of the lactone group-containing skeleton increases in the order of materials A, B, C and D.

TABLE 1

| | Material A | Material B | Material C | Material D |
|---|---|---|---|---|
| l | 5 | 4 | 3 | 2 |
| m | 2 | 2 | 2 | 2 |
| n | 3 | 4 | 5 | 6 |
| Lactone group- | 10.7 | 15.0 | 19.7 | 24.8 |
| containing | | | | |
| skeleton (wt %) | | | | |

The resist materials including the materials A to D respectively were applied on the silicone substrates and the resist films of 250 nm in film thickness were formed. Then, plasma processing using an O₂/HBr gas, plasma processing using an O₂/CF₄ gas and plasma processing using an O₂/Cl₂ gas were performed on the substrates where the resist films were provided respectively. In this regards a flow rate of each gas was 20 ml/min, and the time for the thickness of the resist film being etched from 250 nm to 120 nm was defined as the processing time.

Then, Fourier transform infrared absorption spectrum (FT-IT spectrum) of each resist film was measured before and after the plasma processing. Peaks of the lactone groups chemically bonding to methacrylic acid units constituting the backbone chain of the polymeric materials became low in the plasma processing using each gas. Particularly, remarkable falls of the peaks were obtained in the plasma processing using the O₂/HBr gas. Accordingly, it was verified that the lactone group was eliminated from the polymeric material using each gas and more lactone groups were eliminated by the plasma processing using the O₂/HBr gas compared with the other gases. Further, Table 2 shows the results of residual ratios of the free lactone group eliminated by the plasma processing in the resist films calculated from the FT-IR spectrum. It should be noted that the residual ratio represents a relative ratio in the case of an initial quantity of the lactone group of each resist film before the plasma processing being 1.

TABLE 2

| | Material A | Material B | Material C | Material D |
|---|---|---|---|---|
| Initial quantity | 1.0 | 1.0 | 1.0 | 1.0 |
| Residual ratio | 0.32 | 0.30 | 0.28 | 0.31 |
| after O₂/HBr | | | | |
| treatment | | | | |
| Residual ratio | 0.04 | 0.03 | 0.05 | 0.06 |
| after O₂/CF₄ | | | | |
| treatment | | | | |
| Residual ratio | 0.02 | 0.01 | 0.04 | 0.02 |
| after O₂/Cl₂ treatment | | | | |

As shown in Table 2, it was verified that in all the materials A to D, the resist film after the plasma processing using the O₂/HBr gas had a remarkably high residual ratio of the free lactone group in comparison with the resist films after the plasma processing using the O₂/CF₄ gas and after the plasma processing using the O₂/Cl₂ gas. Further, in the materials A to D, the residual ratios of the lactone group were about 0.3 in the case of each initial quantity being 1. Since the initial quantity of the lactone group increases in the order of the materials A, B, C and Dr the residual quantity of the lactone group increases in -the order of materials A, B, C, and D. Specifically, the residual quantity of the free lactone group depends on a wt % of the lactone group-containing skeleton.

Next, Table 3 shows the change of a glass transition temperature after the plasma processing on resist films including materials A to D, respectively.

TABLE 3

| | Material A | Material B | Material C | Material D |
|---|---|---|---|---|
| Lactone group- | 10.7 | 15.0 | 19.7 | 24.8 |
| containing skeleton | | | | |
| (wt %) | | | | |
| Initial glass | 149 | 150 | 150 | 151 |
| transition | | | | |
| temperature (° C.) | | | | |
| Temperature after | 85 | 70 | 65 | 54 |
| O₂/HBr treatment(° C.) | | | | |

As shown in Table 3, it was verified that the fall of glass transition temperature after performing the plasma processing increased in the order of materials A, B, C, and D. Specifically, it was verified that the fall of glass transition temperature depended on the residual quantity of the lactone group in the resist film and the larger the wt % of the lactone group-containing skeleton in the resist material is, the more remarkably the glass transition temperature or softening point falls.

[Verification Test 2]

Next, a verification test was carried out regarding the fall of a softening point of each resist film in the case where the plasma processing using a hydrogen-containing gas was performed on resist films including the materials A to D, respectively.

After having formed resist films of 250 nm in thickness including the materials A to D respectively on silicone substrates, the plasma processing using the HBr gas was performed on the substrates on which resist films were provided respectively. In that case, a flow rate of the HBr gas was 40 ml/min, and processing time was 30 sec. Here, the reduction in the resist film thickness by the plasma processing was not observed.

Then, FT-IR spectrum of each resist film was measured before and after the plasma processing. The residual ratio of the free lactone group eliminated by the plasma processing in the resist film was calculated based on the FT-IR spectrum in the case of the initial quantity of the lactone group of each resist film before the processing being 1. Table 1 shows the results.

TABLE 4

| | Material A | Material B | Material C | Material D |
|---|---|---|---|---|
| Initial quantity | 1.0 | 1.0 | 1.0 | 1.0 |
| Residual ratio | 0.40 | 0.54 | 0.55 | 0.60 |
| after O₂/HBr | | | | |
| treatment | | | | |

As shown in Table 4, it was verified that the free lactone group remained in each of the resist films including materials A to D respectively after the plasma processing using the HBr gas, and the residual ratio of the lactone group increased in the order of materials A, B, C, and D and the residual quantity of the lactone group also increased in the order of materials A, B, C, and D.

The Table 5 shows the change of the softening point before and after the plasma processing on the resist films including materials A to D respectively.

TABLE 5

| | Material A | Material B | Material C | Material D |
|---|---|---|---|---|
| Lactone group- | 10.7 | 15.0 | 19.7 | 24.8 |
| containing skeleton | | | | |
| (Wt %) | | | | |
| Initial softening | 226 | 225 | 229 | 230 |
| point (° C.) | | | | |
| Softening point after | 180 | 170 | 160 | 151 |
| O₂/HBr treatment (° C.) | | | | |

As shown in Table 5, it was verified that the fall of the softening point after plasma processing was large in the order of materials A, B, C, and D. Specifically, it was verified that the fall of the softening point depended on the residual quantity of the free lactone group in the resist film and the larger the wt % of the lactone group-containing skeleton in the resist material is, the more remarkably the softening point falls.

### PRACTICE EXAMPLE

A pattern forming method and a method of manufacturing semiconductor devices using that method according to an embodiment are explained in the followings. Here, gate electrodes are formed using the same method as the embodiment explained with reference to FIGS. 1 and 2.

First, as explained using FIG. 1A, a gate electrode film 12 made of polysilicone was formed with 180 nm in thickness on a substrate 11 made of a silicone wafer through a gate-insulated film (not shown) formed with 3 nm in thickness made of an oxide silicone film. Next, after forming a protective film 13 made of TEOS (Tetraethoxysilane) with 60 nm in thickness on the gate electrode film 12, an antireflective coating (for example, antireflective coating AR40 manufactured by Rohm & Haas Company) 14 made of thermosetting resin was formed with 90 nm in thickness by a spin-coating method, and baking treatment was performed at 215° C. for 90 sec. Subsequently, respective resist materials including the above-described materials A to D were applied to the antireflective coating 14 by the spin-coating method, and after a resist film 15 was formed with 250 nm in thickness, the baking treatment was performed at 110° C. for 60 sec.

Next, the substrate 11 in such condition was introduced into a photolithography machine (for example, ArF exposing apparatus S308-F manufactured by Nikon Corporation) and the exposure for line and space was performed on the resist film 15. The exposure conditions were set to: NA 0.75, annular illumination, and σ (outer)=0.75 and σ (inner)=0.50; and an exposure quantity is set to 33 mJ/cm².

Subsequently, as explained using FIG. 1B, the baking treatment was performed at 95° C. for 60 sec. on the substrate 11 where the resist film 15 after the exposure was provided, and then the resist pattern 15′ was formed by developing the substrate 11 using an alkali developer.

Next, as explained using FIG. 1C, after performing the patterning on the antireflective coating 14 by the etching using the resist pattern 15′ as a mask, trim etching was performed on the resist pattern 15′ and on the pattern of the antireflective coating 14. Accordingly, the line widths of the resist pattern 15′ and pattern of the antireflective coating 14 were made thin. The pattern was here formed with the line width 90 nm and pitch 180 nm, for example.

Plasma processing using the HBr gas was performed on the substrate 11 in such condition. The plasma processing conditions were similar to those of the first embodiment: a flow rate of the HBr gas was 40 ml/min; source power was 300 W, pressure was 0.53 Pa; and processing time was 10 sec. Also, temperature of a stage that holds the substrate 11 was room temperature.

After that, as explained using FIG. 1D, after the patterning on a protective film 13 by the etching using the resist pattern 15′ as a mask, as explained using FIG. 2A, the resist pattern 15′ (see FIG. 1D) and the antireflective coating 14 (see FIG. 1D) were removed by ashing and the pattern of the protective film 13 was exposed.

Subsequently, as explained using FIG. 2B, a plurality of gate electrodes 12′ were formed by patterning a gate electrode film 12 (see FIG. 2A) by means of etching using the pattern of the protective film 13 as a mask.

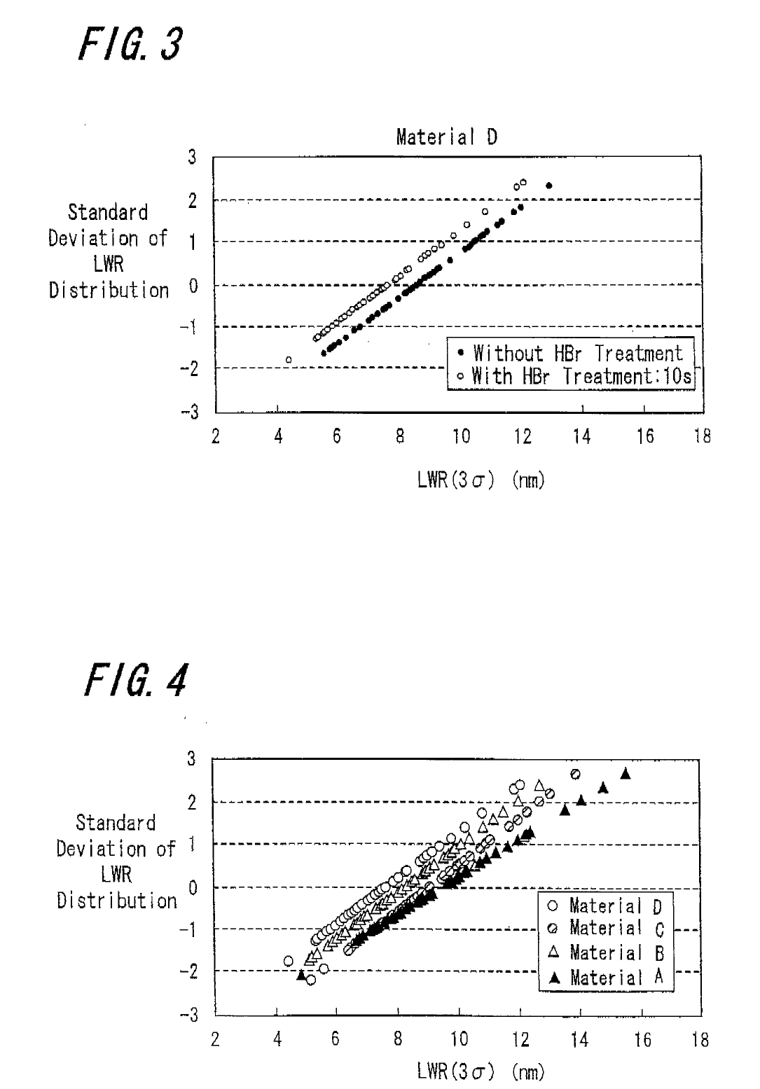

Then, the gate electrodes 12′ formed on the substrate 11 were observed by length measurement SEM at a plurality of (about 30) areas and the LWR (Line Width Roughness) of a line pattern (gate line width W) was measured. A horizontal axis in FIG. 3 represents the LWR of the gate electrodes 12′ to which the resist pattern 15′ including material D is transferred. The LWR was defined as three times the standard deviation (σ) of dispersion of line widths in the area of about 0.39 μm in length. In order to clearly indicate that the LWR was defined as three times the standard deviation, the horizontal axis in FIG. 3 was described as LWR (3σ). Since the gate line width W of the gate electrodes 12′ was measured at a plurality of areas (about 30), the plurality of measured values (about 30) were obtained for each of experimental conditions as the LRW measured values. The standard deviation of distribution of the plurality of LWR is a unit of vertical axis in FIG. 3. Specifically, the vertical axis represents standard deviation of the distribution of standard deviation. In the graph, a position 0 (zero) in the vertical axis indicates an average value of the plurality of LWR (3σ) values (about 30).

As shown in the graph of FIG. 3, an average value of LWR (3σ) using the resist pattern 15′ after the plasma processing is 8 nm or less, and an average value of LWR (3σ) without plasma processing is 8 nm or more, Accordingly, it is confirmed that the plasma processing on the resist pattern 15′ causes LWR (3σ) to be small.

Further, FIG. 4 is a graph showing standard deviation a that represents the distribution of LWR (3σ) values in the vertical axis, while the horizontal axis represents LWR (3σ) of the gate electrodes 12′ to which the resist patterns including materials A to D are transferred respectively.

As shown in the graphs though the result is reversed between material B and material C, LWR (3σ) has a tendency toward being small by performing the plasma processing on the resist pattern 15′ in accordance with the increases in the wt % based on the lactone group-containing skeleton.

Particularly, in the case of performing the plasma processing using the HBr on the resist pattern including the material D, an average value of LWR (3σ) is 8 nm or less, and consequently it is Confirmed that LWR (3σ) becomes remarkably small.

It should be understood by those skilled in the art that various modifications, combinations, sub-combinations and alterations may occur depending on design requirements and other factors insofar as they are within the scope of the appended claims or the equivalents thereof.

What is claimed is:

1. A pattern forming method comprising:
a first step of forming a resist pattern including a lactone group-containing skeleton above an etched layer provided on a substrate;
a second step of performing plasma processing using a hydrogen-containing gas to lower a glass transition temperature or a softening point of said resist pattern; and
a third step of transferring said resist pattern after the plasma processing to said etched layer by etching, and forming the pattern of said etched layer.

2. The pattern forming method according to claim 1, wherein
a weight ratio of said lactone group-containing skeleton to a polymeric material constituting said resist pattern is 20 wt % or more and 35 wt % or less.

3. The pattern forming method according to claim 1, wherein
said resist pattern is formed above said etched layer through an antireflective coating in said first step; and
a step of forming the pattern of said antireflective coating by etching using said resist pattern as a mask is included after said first step and before said third step.

4. The pattern forming method according to claim 3, wherein
said plasma processing is performed further to form the pattern of said antireflective coating in said second step.

5. The pattern forming method according to claim 1, further comprising the step of:
performing thermal treatment between said second step and said third step.

6. The pattern forming method according to claim 5, wherein
said thermal treatment is performed in a temperature higher than the lowered glass transition temperature or softening point of said resist pattern.

7. The pattern forming method according to claim 5, wherein
said plasma processing in said second step further serves as said thermal treatment.

8. The pattern forming method according to claim 5, further comprising the step of:
performing said thermal treatment between said second step and said third step.

9. The pattern forming method according to claim 5, wherein
forming the pattern of said etched layer in said third step further serves as said thermal treatment.

10. A method of manufacturing a semiconductor device, comprising:
a first step of forming a resist pattern including a lactone group-containing skeleton above a gate electrode film provided on a substrate;
a second step of performing plasma processing using a hydrogen-containing gas to lower a glass transition temperature or a softening point of said resist pattern; and
a third step of transferring said resist pattern after the plasma processing to said etched layer by etching, and forming the gate electrode of said etched layer.
